(19) United States
(12) Patent Application Publication
(10) Pub. No.: US 2017/0213892 A1
(43) Pub. Date: Jul. 27, 2017

(54) NANOSTRUCTURES AND NANOFEATURES WITH Si (111) PLANES ON Si (100) WAFERS FOR III-N EPITAXY

(71) Applicant: Intel Corporation, Santa Clara, CA (US)

(72) Inventors: Sansaptak Dasgupta, Hillsboro, OR (US); Han Wui Then, Portland, OR (US); Sanaz K. Gardner, Portland, OR (US); Benjamin Chu-Kung, Hillsboro, OR (US); Marko Radosavljevic, Beaverton, OR (US); Seung Hoon Sung, Portland, OR (US); Robert S. Chau, Beaverton, OR (US)

(21) Appl. No.: 15/481,200

(22) Filed: Apr. 6, 2017

Related U.S. Application Data
(62) Division of application No. 14/779,257, filed on Sep. 22, 2015.

(51) Int. Cl. H01L 29/205; H01L 21/324; H01L 21/02; H01L 21/308; H01L 29/04; H01L 29/06

(52) U.S. Cl. CPC H01L 29/205; H01L 29/045; H01L 29/0649; H01L 29/0684; H01L 21/02381; H01L 21/0254; H01L 21/02609; H01L 21/308; H01L 21/324

(57) ABSTRACT

A fin over an insulating layer on a substrate having a first crystal orientation is modified to form a surface aligned along a second crystal orientation. A device layer is deposited over the surface of the fin aligned along the second crystal orientation.

### CROSS REFERENCE TO RELATED APPLICATIONS

This application is a divisional of co-pending U.S. application Ser. No. 14/779,257 filed on Sep. 22, 2015, which claims the benefit of U.S. National Phase Application under 35 U.S.C. §371 of International Application No. PCT/US2013/48757, filed Jun. 28, 2013, entitled “Nanostructures And Nanofeatures With Si (111) Planes On Si (100) Wafers For III-N Epitaxy”, which is incorporated by reference in its entirety.

### TECHNICAL FIELD

Embodiments as described herein relate to the field of electronic device manufacturing, and in particular, to manufacturing of III-V materials based devices.

### BACKGROUND ART

Generally, to integrate III-V materials on a silicon (“Si”) substrate aligned along a <100> crystal orientation (“Si (100)”) for system-on-chip (“SoC”) high voltage and radio frequency (“RF”) devices with Complementary Metal Oxide Semiconductor (“CMOS”) transistors, great challenges arise due to dissimilar lattice properties of the III-V materials and silicon. Typically, when a III-V material is grown on a silicon (“Si”) substrate defects are generated due to the lattice mismatch between the III-V material and Si. These defects can reduce the mobility of carriers (e.g., electrons, holes, or both) in the III-V materials.

Currently, integration of GaN (or any other III-N material) on Si (100) wafer involves the use of thick buffer layers (>1.5 um) and starting miscut Si (100) wafer with 2-8° miscut angle to provide a low enough defect density layer for the growth of the device layers. Typically, integration of GaN (or any other III-N material) on Si (100) wafer involves a blanket epitaxial growth process.

Large lattice mismatch (about 42%) between gallium nitride (“GaN”) and Si (100) causes generation of a lot of undesirable defects when the GaN is grown on Si (100) substrate that cannot be used for a device fabrication. Accordingly, the large lattice mismatch between the III-V materials and Si provides a great challenge for an epitaxial growth of III-V materials on a Si (100) substrate for device fabrication.

In addition, a large thermal mismatch (about 116%) between the GaN and Si combined with the conventional high growth temperatures for GaN, results in the formation of surface cracks on the epi-layers, thus making them unsuitable for device fabrication.

### BRIEF DESCRIPTION OF THE DRAWINGS

FIG. 1 shows a cross-sectional view of an electronic device structure according to one embodiment.

FIG. 2 is a view similar to FIG. 1, after fins are formed on the substrate aligned along a predetermined crystal orientation according to one embodiment.

FIG. 3 is a view similar to FIG. 2, after an insulating layer is deposited on substrate 101 between the fins, and the hard mask is removed according to one embodiment.

FIG. 4 is a cross-sectional view of a portion of an electronic device structure shown in FIG. 3 according to one embodiment.

FIG. 5 is a view similar to FIG. 4 illustrating modifying a fin over an insulating layer on a substrate to expose a surface aligned along a second crystal plane corresponding to a second crystal orientation according to one embodiment.

FIG. 6 is a view similar to FIG. 5 after the fin has been modified according to one embodiment.

FIG. 7 is a cross-sectional view of a portion of an electronic device structure shown in FIG. 2 after an insulating layer is deposited on a substrate between the fins, and a hard mask is removed according to another embodiment.

FIG. 8 is a view similar to FIG. 7 after the fin is anisotropically etched according to another embodiment.

FIG. 9 is a view similar to FIG. 8 after the insulating layer is recessed according to one embodiment.

FIG. 10 is a perspective view of an electronic device structure having a fin as depicted in FIG. 6 according to one embodiment.

FIG. 11 is a perspective view of an electronic device structure having a fin as depicted in FIG. 9 according to one embodiment.

FIG. 12 is a perspective view of an electronic device structure having a fin as depicted in FIG. 8 according to one embodiment.

FIG. 13 is a cross-sectional view similar to FIG. 6, after an optional nucleation/seed layer is deposited on the surface of the fin aligned along the second crystal orientation, a device layer is deposited on the nucleation/seed layer, and a polarization inducing layer is deposited on the device layer according to one embodiment.

FIG. 14 is a cross-sectional view similar to FIG. 9, after an optional nucleation/seed layer is deposited on the surface of the fin aligned along the second crystal orientation, a device layer is deposited on the nucleation/seed layer, and a polarization inducing layer is deposited on the device layer according to one embodiment.

FIG. 15 is a perspective view of an electronic device structure as depicted in FIG. 16.

FIG. 16 is a cross-sectional view similar to FIG. 6, after a device layer is deposited on the surface of the fin aligned along the second crystal orientation, and a polarization inducing layer is deposited on the device layer according to another embodiment.

FIG. 17 is a cross-sectional view similar to FIG. 6, after an optional nucleation/seed layer is deposited on the surface of the fin aligned along the second crystal orientation, a device layer is deposited on the nucleation/seed layer, and a polarization inducing layer is deposited on the device layer according to another embodiment.

FIGS. 18A-1, 18A-2, and 18A-3 show cross sectional scanning electron microscope (“XSEM”) pictures of the embodiments of the structures as described herein.

FIGS. 18B-1, 18B-2, and 18B-3 show pictures depicting the fins having different dimensions, after the fins have been etched in a TMAH solution for the same time according to one embodiment.

FIG. 19 is a view 1900 of a picture 1901 showing the reshaping of the fins with the high temperature anneal according to one embodiment.

FIGS. 20-1, 20-2, 21-1, and 21-2 illustrate growth of the III-N material layers on Si (111) like planes according to an embodiment.

FIG. 22 illustrates a computing device in accordance with one embodiment.

### DESCRIPTION OF THE EMBODIMENTS

In the following description, numerous specific details, such as specific materials, dimensions of the elements, etc. are set forth in order to provide thorough understanding of one or more of the embodiments as described herein. It will be apparent, however, to one of ordinary skill in the art that the one or more embodiments as described herein may be practiced without these specific details. In other instances, semiconductor fabrication processes, techniques, materials, equipment, etc., have not been described in great detail to avoid unnecessary obscuring of this description.

While certain exemplary embodiments are described and shown in the accompanying drawings, it is to be understood that such embodiments are merely illustrative and not restrictive, and that the embodiments are not restricted to the specific constructions and arrangements shown and described because modifications may occur to those ordinarily skilled in the art.

Reference throughout the specification to “one embodiment”, “another embodiment”, or “an embodiment” means that a particular feature, structure, or characteristic described in connection with the embodiment is included in at least one embodiment. Thus, the appearance of the phrases, such as “one embodiment” and “an embodiment” in various places throughout the specification are not necessarily all referring to the same embodiment. Furthermore, the particular features, structures, or characteristics may be combined in any suitable manner in one or more embodiments.

Moreover, inventive aspects lie in less than all the features of a single disclosed embodiment. Thus, the claims following the Detailed Description are hereby expressly incorporated into this Detailed Description, with each claim standing on its own as a separate embodiment. While the exemplary embodiments have been described herein, those skilled in the art will recognize that these exemplary embodiments can be practiced with modification and alteration as described herein. The description is thus to be regarded as illustrative rather than limiting.

Methods and apparatuses to manufacture an electronic device are described herein. A fin over an insulating layer on a substrate aligned along a first crystal orientation is modified to form a surface aligned along a second crystal orientation. A device layer is deposited over the surface of the fin aligned along the second crystal orientation. In at least some embodiments, the substrate includes silicon, and the device layer includes a III-V material. Generally, the III-V material refers to a compound semiconductor material that comprises at least one of group III elements of the periodic table, e.g., aluminum (“Al”), gallium (“Ga”), indium (“In”), and at least one of group V elements of the periodic table, e.g., nitrogen (“N”), phosphorus (“P”), arsenic (“As”), antimony (“Sb”).

In an embodiment, a method to form Si nanofins with exposed surfaces aligned along a <111> crystal orientation (“(111) planes”) on a Si (100) wafer is described. The Si nanofins (nanofeatures) with exposed (111) planes provide excellent templates for epitaxial growth of III-V (e.g., III-Nitride (“N”)) epitaxial layers. Generally, the III-N epitaxial layers have lesser lattice mismatch to Si (111) than to Si (100). For example, GaN on Si (100) has a lattice mismatch of 40% whereas GaN on Si (111) has a lattice mismatch of ˜17%. Si (111) lattice unit cell has hexagonal symmetry and hence is appropriate for III-N material growth which also has a hexagonal crystal structure. This is opposed to Si (100) which has a cubic lattice structure, and hence growing the hexagonal GaN crystals may result in problems of orienting hexagonal GaN crystals on cubic Si (100) unit cells.

At least some embodiments described herein refer to creation of (111) Si nanofeatures on Si (100) thus enabling improved epitaxy of III-N materials on Si nanotemplates. The nanotemplates enable the utilization of benefits of free surface relaxation during epitaxial growth and the fin-like dimension leads to substrate compliance which can lead to integration of III-N materials without the use of buffer layers and reduction of the density of defects of the III-V materials on silicon (100). As a parent wafer is still Si (100), creation of (111) Si nanofeatures on Si (100) enables the integration of III-N on large sized Si (100) wafers for both system-on-chip (“SoC”) applications and other electronic device systems.

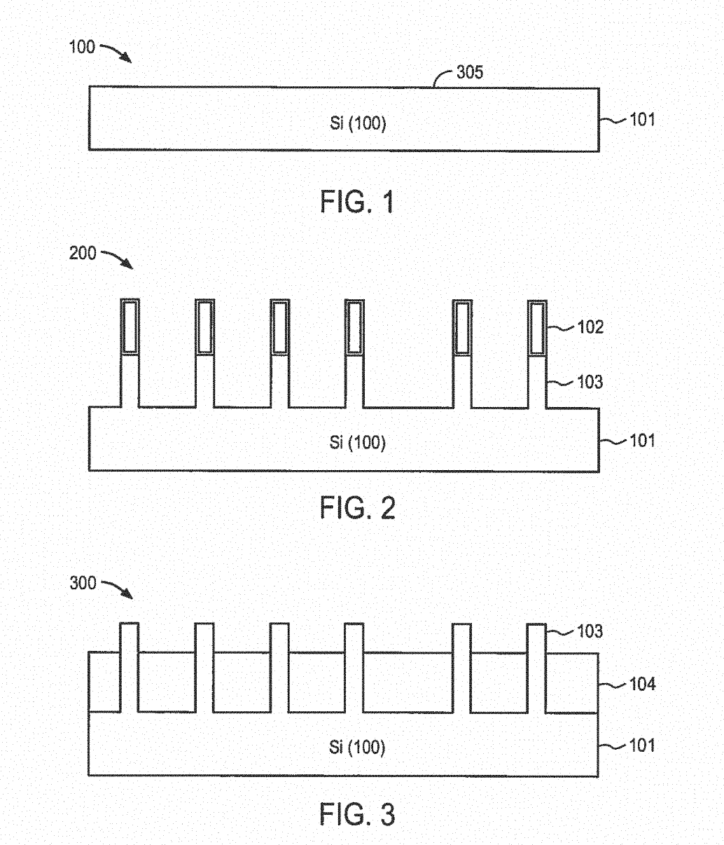

FIG. 1 shows a cross-sectional view 100 of an electronic device structure according to one embodiment. The electronic device structure comprises a substrate 101. In an embodiment, the substrate 101 is a substrate having a top surface 103 aligned along a predetermined crystal orientation.

Generally, the crystallographic orientation refers to a direction linking nodes (e.g., atoms, ions or molecules) of a crystal. A crystallographic plane typically refers to a plane linking the nodes (e.g., atoms, ions or molecules) along a crystallographic orientation of a crystal. Generally, the crystallographic orientations and crystallographic planes are defined by Miller indexes (e.g., <100>, <111>, <110>, and other Miller indexes), as known to one of ordinary skill in the art of electronic device manufacturing. Typically, some directions and planes of the crystal have a higher density of nodes than other directions and planes of the crystal.

In an embodiment, the substrate 101 includes a semiconductor material, e.g., monocrystalline silicon (“Si”), germanium (“Ge”), silicon germanium (“SiGe”), a III-V materials based material e.g., gallium arsenide (“GaAs”), or any combination thereof having a top surface aligned along a predetermined crystal orientation. In one embodiment, the substrate 101 includes metallization interconnect layers for integrated circuits. In at least some embodiments, the substrate 101 includes electronic devices, e.g., transistors, memories, capacitors, resistors, optoelectronic devices, switches, and any other active and passive electronic devices that are separated by an electrically insulating layer, for example, an interlayer dielectric, a trench insulation layer, or any other insulating layer known to one of ordinary skill in the art of the electronic device manufacturing. In at least some embodiments, the substrate 101 includes interconnects, for example, vias, configured to connect the metallization layers.

In an embodiment, substrate 101 is a semiconductor-on-isolator (SOI) substrate including a bulk lower substrate, a middle insulation layer, and a top monocrystalline layer aligned along a predetermined crystal orientation, for example, <100> crystal orientation. The top monocrystalline layer may comprise any material listed above, e.g., silicon.

In an embodiment, substrate 101 is a silicon substrate aligned along a <100> crystal orientation (“Si (100)”).

FIG. 2 is a view 200 similar to FIG. 1, after fins are formed on the substrate aligned along a predetermined crystal orientation according to one embodiment. As shown in FIG. 2, fins, such as a fin 103 are formed on substrate 101. As shown in FIG. 2, a patterned hard mask 102 is deposited on substrate 101. Hard mask 102 can be formed on the substrate 101 using one of patterning and etching techniques known to one of ordinary skill in the art of electronic device manufacturing. In an embodiment, the portions of the substrate 101 not covered by hard mask 102 are etched to a predetermined depth to form fins, such as fin 103. As shown in FIG. 2, each of the fins 103 has a top surface and two opposing sidewalls adjacent to the top surface.

Hard mask 102 is on the top surface of each of the fins. As shown in FIG. 2, the fins are separated from each other on substrate 101 by a distance. In an embodiment, the distance between the fins 103 on substrate 101 is at least 100 nanometers (“nm”), and more specifically, at least 200 nm. In an embodiment, the distance between the fins 103 on substrate 101 is in an approximate range from about 30 nm to about 300 nm.

FIG. 3 is a view 300 similar to FIG. 2, after an insulating layer is deposited on substrate 101 between the fins, and the hard mask is removed according to one embodiment. An insulating layer 104 is deposited between the fins 103, as shown in FIG. 3. Insulating layer 104 can be any material suitable to insulate adjacent devices and prevent leakage. In one embodiment, electrically insulating layer 104 is an oxide layer, e.g., silicon dioxide, or any other electrically insulating layer determined by an electronic device design. In one embodiment, insulating layer 104 comprises an interlayer dielectric (ILD), e.g., silicon dioxide. In one embodiment, insulating layer 102 may include polyimide, epoxy, photodefinable materials, such as benzocyclobutene (BCB), and WPR-series materials, or spin-on-glass. In one embodiment, insulating layer 104 is a low permittivity (low-k) ILD layer. Typically, low-k is referred to the dielectrics having dielectric constant (permittivity k) lower than the permittivity of silicon dioxide.

In one embodiment, insulating layer 104 is a shallow trench isolation (STI) layer to provide field isolation regions that isolate one fin from other fins on substrate 101. In one embodiment, the thickness of the layer 104 is in the approximate range of 500 angstroms (Å) to 10,000 Å. The insulating layer 104 can be blanket deposited using any of techniques known to one of ordinary skill in the art of electronic device manufacturing, such as but not limited to a chemical vapour deposition (CVD), and a physical vapour deposition (PVP), and then polished back to remove the insulating layer 104 and hard mask 102 and expose the fins. The hard mask layer can be removed from the top of the fin 103 by a polishing process, such as a chemical-mechanical planarization (“CMP”) process as known to one of ordinary skill in the art of electronic device manufacturing. In an embodiment, the insulating layer 104 between the fins 103 is recessed down to a depth determined by a device design for example, using one of the etching techniques known to one of ordinary skill in the art of electronic device manufacturing.

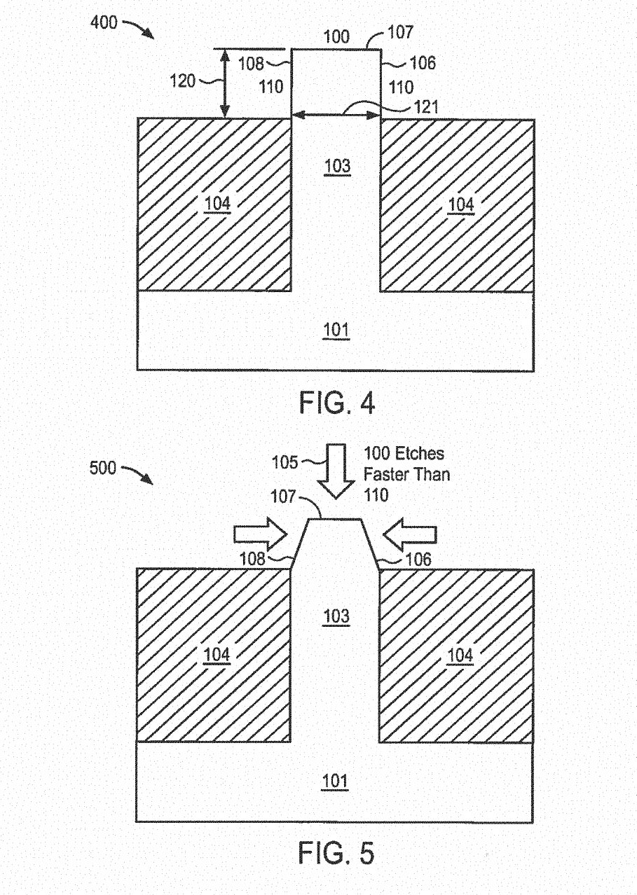

FIG. 4 is a cross-sectional view 400 of a portion of an electronic device structure shown in FIG. 3 according to one embodiment. Fin 103 is formed over insulating layer 104 on substrate 101. As shown in FIG. 4, fin 103 has a top surface 107, a sidewall 106 and a sidewall 108. Insulating layer 104 is recessed from top surface 107 down to a depth 108. In one embodiment, insulating layer 104 is recessed while leaving the fin 103 intact using a selective etching technique known to one of ordinary skill in the art of electronic device manufacturing, such as but not limited to a wet etching, and a dry etching with the chemistry having substantially high selectivity to the fin on the substrate 101. This means that the chemistry predominantly etches the insulating layer 104 rather than the fin of the substrate 101. In one embodiment, a ratio of the etching rates of the insulating layer 104 to the fin is at least 10:1. In an embodiment, insulating layer 104 of silicon oxide is selectively etched using a hydrofluoric acid (“HF”) solution, as known to one of ordinary skill in the art of electronic device manufacturing.

As shown in FIG. 4, insulating layer 104 is recessed down to a depth 120 that defines the height (“Hsi”) of the fin 103 relative to the top surface of the insulation layer 104. The height 120 and the width (“Wsi”) 121 of the fin 103 are typically determined by a design. In an embodiment, the height 120 of the fin 103 relative to the top surface of the insulation layer 104 is from about 10 nm to about 200 nm and the width of the fin 109 is from about 5 nm to about 100 nm. In an embodiment, the height 120 of the fin 103 relative to the top surface of the insulation layer 104 is from about 10 nm to about 80 nm. In an embodiment, the width of the fin 109 is from about 10 nm to about 100 nm. In an embodiment, the width 121 of the fin is less than the height 120 of the fin. The fin 103 has a top surface 107 aligned along a first crystal plane corresponding to a first crystal orientation of the substrate 101. The first crystal plane can be any crystal plane, e.g., 100, 110, 111, or any other crystal plane. In an embodiment, the sidewalls 106 and 108 of the fin are aligned along a crystal plane (110) corresponding to a <110> crystal orientation, and top surface 107 of the fin is aligned along a crystal plane (100) corresponding to a <100> crystal orientation. In other embodiments, the sidewalls 106 and 108 are aligned long other crystal planes corresponding to other crystal orientations, e.g., a crystal plane (100). In an embodiment, fin 103 represents an initial fin oriented along (100) crystal plane.

FIG. 5 is a view 500 similar to FIG. 4 illustrating modifying a fin over an insulating layer on a substrate to expose a surface aligned along a second crystal plane corresponding to a second crystal orientation according to one embodiment. The second crystal plane can be any crystal plane, e.g., 111, 110, 100, or any other crystal plane. The fin aligned along a first crystal plane can be modified to create the nanotemplates with a surface aligned along a second crystal plane different from the second crystal plane using many methods.

Ex-Situ Formation

In an embodiment, the fin etched to expose the surface aligned along a crystal plane corresponding to a crystal orientation that is different from the orientation of the substrate. In an embodiment, fin 103 is anisotropically etched 105 to expose a surface aligned along the crystal orientation (e.g., a (111) crystal plane) that is different from the crystal orientation of the substrate 101 (e.g., a (100) crystal plane). As shown in FIG. 5, top surface 107 corresponding to a (100) crystal plane is etched faster than sidewalls 108 and 106 corresponding to (110) crystal plane to expose a surface of the fin corresponding to a (111) plane. In an embodiment, an etching solution (e.g., Tetramethylammonium hydroxide (“TMAH”), potassium hydroxide (“KOH”), ammonium hydroxide (“NH4OH”)) is used to anisotropically etch the Si fin to expose a surface of the fin corresponding to a (111) crystal plane. In an embodiment, the Si fin is oriented such that the sidewalls are (110) planes. During an anistropic etch (e.g., using TMAH, KOH, NH4OH based solutions), the (100) plane is typically the fastest to etch. The etch nominally stops on the (111) plane, due to its high density of atomic bonds.

In-Situ Formation

In an embodiment, the fin is annealed to form the surface aligned along a crystal plane corresponding to a crystal orientation that is different from the orientation of the substrate. In an embodiment, the Si (111) like planes are formed in-situ in a MOCVD chamber prior to a III-N epi growth. A high temperature hydrogen gas (“H₂”) annealing results in formation of Si (111) like planes from the initial Si fins. In an embodiment, hydrogen is adsorbed at the surface of the Si (100) fin by annealing that causes the Si atoms to move to form strongest bonds along a (111) plane. In an embodiment, the fins are subjected to high temperatures (e.g., more than about 800° C., and more specifically, more than about 1000° C.) during the GaN growth process and a surface reflow of Si from the Si fins results in a more rounded fin template with (111) like planes. In an embodiment, an in-situ fin reflow temperature used to reshape the (100) Si fins to expose a (111) surface is in an approximate range from about 850° C. to about 1100° C. under a flow of hydrogen (“H₂”) of about 5 standard liter per minute (“slm”) to about 100 slm for an approximate time range from about 30 seconds to about 600 second.

FIG. 6 is a view 600 similar to FIG. 5 after the initial fin 103 has been modified according to one embodiment. In an embodiment, fin 103 initially aligned along a first crystal plane corresponding to a first crystal orientation (e.g., (100) crystal plane) is modified (e.g., by anisotropic etching, annealing, or both) to form a surface 126 and a surface 128 aligned along a second crystal plane corresponding to a second crystal orientation (e.g., (111) crystal plane). In an embodiment, the fin 103 is modified to expose the surfaces 126 and 128 corresponding to the second crystal plane. As shown in FIG. 6, top surface 107 corresponding to the first crystal plane after modifying becomes substantially smaller than the width 129 of the fin 103 at a level of a top surface of the insulating layer 104.

In an embodiment, a portion 131 of the fin 103 above insulating layer 104 has a substantially triangular shape (“Structure A”). As shown in FIG. 6, top surface 107 corresponding to a (100) crystal plane is substantially etched out. Surfaces 126 and 128 corresponding to a (111) crystal plane are adjacent to each other at the top surface vertex 107 forming the triangular shape. Generally, the final shape of the modified fin depends on the temperature of the etching solution, an initial fin height H_{Si} and width W_{Si} an initial orientation of the fin, annealing temperature, or any combination thereof, and is determined by a device design. For example, Structure A can be obtained if the initial H_{Si} is greater than the initial width W_{Si} of the fin.

In an embodiment, a TMAH wet etch solution at a temperature from about 30° C. to about 100° C. for time from about 5 seconds to about 100 seconds is used to anisotropically etch the Si fin to expose a surface of the fin corresponding to a (111) crystal plane to create Structure A. In an embodiment, at least one of KOH solution and NH4OH solution at a temperature from about 20° C. to about 80° C. and for time from about 30 seconds to about 150 seconds is used to anisotropically etch the Si fin to expose a surface of the fin corresponding to a (111) crystal plane to create Structure A.

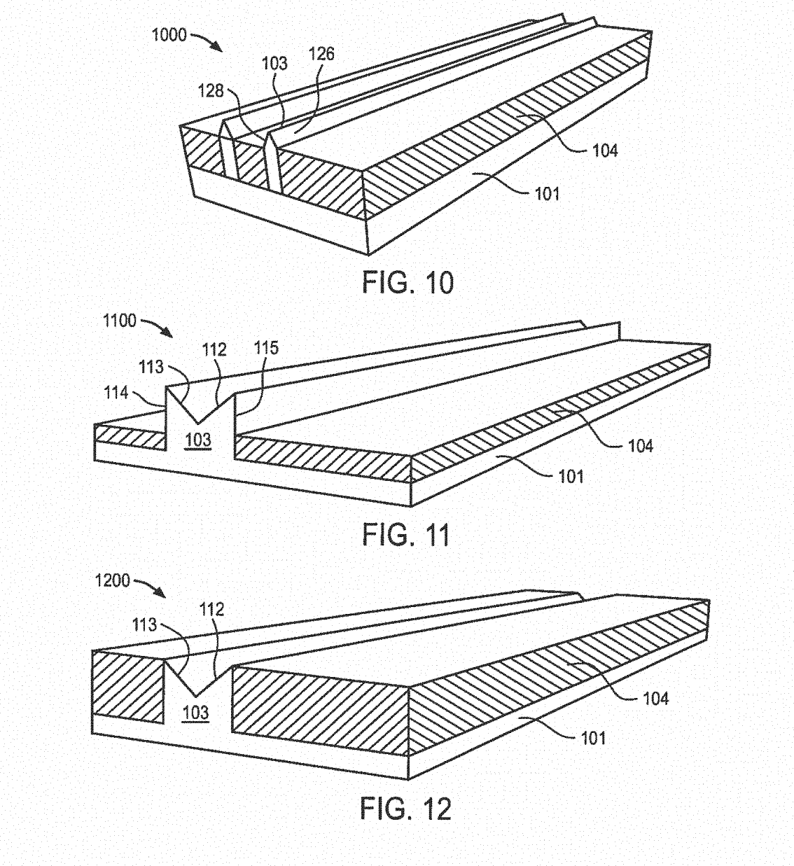

FIG. 10 is a perspective view 1000 of an electronic device structure having a fin as depicted in FIG. 6 according to one embodiment. The electronic device structure has fins, such as fin 103 over insulating layer 104 on substrate 101. Substrate 101 is aligned along a first crystal plane corresponding to a first crystal orientation (e.g., (100) crystal plane), as described above. Each of the fins 103 has a surface 126 and a surface 128 aligned along a second crystal plane corresponding to a second crystal orientation (e.g., (111) crystal plane), as described above.

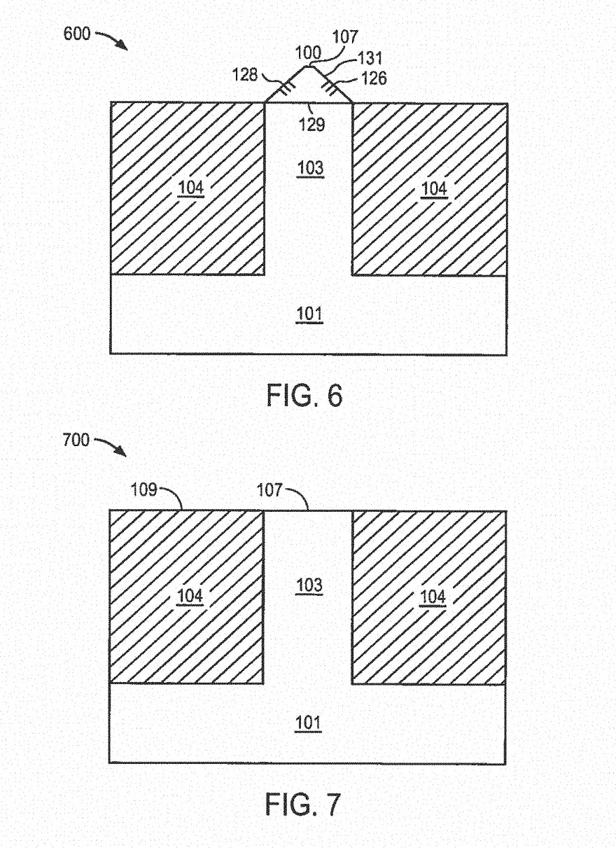

FIG. 7 is a cross-sectional view 700 of a portion of an electronic device structure shown in FIG. 2 after an insulating layer 104 is deposited on substrate 101 between the fins, and the hard mask is removed according to another embodiment. As shown in FIG. 7, top surface 107 of the fin 103 is at the same level as a top surface 109 of the insulating layer 104 on substrate 101. The insulating layer 104 can be blanket deposited using any of techniques known to one of ordinary skill in the art of electronic device manufacturing, such as but not limited to a chemical vapour deposition (CVD), and a physical vapour deposition (PVD), and then polished back to remove the insulating layer 104 and hard mask 102 and expose the top surface 107 of the fins. The hard mask layer can be removed from the top of the fin 103 by a polishing process, such as a chemical-mechanical planarization (“CMP”) process as known to one of ordinary skill in the art of electronic device manufacturing.

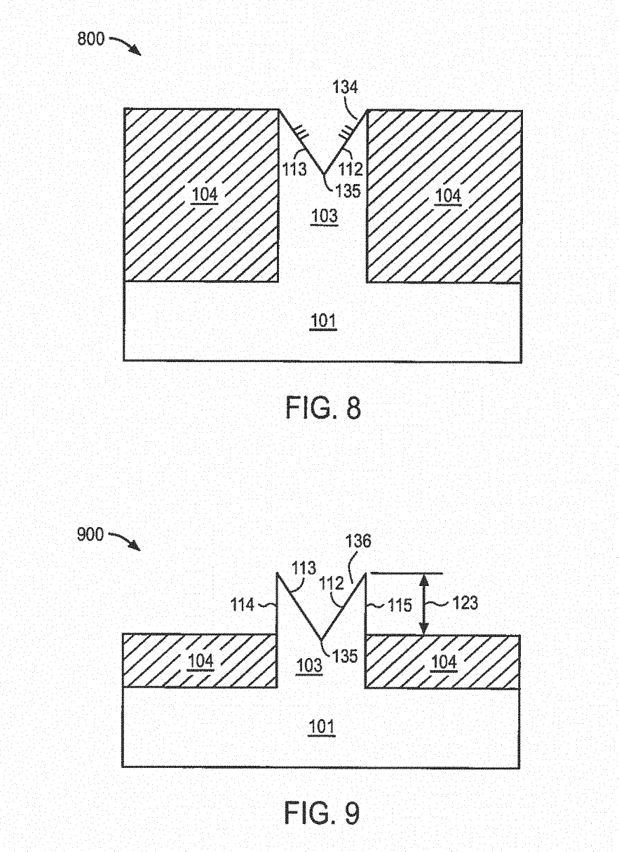

FIG. 8 is a view 800 similar to FIG. 7 after the initial fin 103 is anisotropically etched according to another embodiment. As shown in FIG. 8, fin 103 initially aligned along a first crystal plane corresponding to a first crystal orientation (e.g., (100) crystal plane) is modified by anisotropic etching to form a surface 112 and a surface 113 aligned along a second crystal plane corresponding to a second crystal orientation (e.g., (111) crystal plane). The fin 103 is etched to expose the surfaces 112 and 113 corresponding to the second crystal plane. As shown in FIG. 8, anisotropic etch is used to etch top surface 107 corresponding to a (100) crystal plane. The anisotropic etch terminates on surfaces 112 and 113 corresponding to (111) crystal plane.

As shown in FIG. 8, a top portion 134 of the fin 103 has a V shape (“Structure B”). As shown in FIG. 8, top surface 107 corresponding to (100) crystal plane has been substantially etched out, so that surfaces 132 and 133 corresponding to a (111) crystal plane became adjacent to each other at a base 135.

In an embodiment, a TMAH wet etch solution at a temperature from about 30° C. to about 100° C. for time from about 30 seconds to about 150 seconds is used to anisotropically etch the Si fin to expose a surface of the fin corresponding to a (111) crystal plane to create Structure B.

In an embodiment, at least one of KOH solution and NH4OH solution at a temperature from about 20° C. to about 80° C. and for time from about 30 seconds to about 150 seconds is used to anisotropically etch the Si fin to expose a surface of the fin corresponding to a (111) crystal plane to create Structure B.

FIG. 12 is a perspective view 1200 of an electronic device structure having a fin as depicted in FIG. 8 according to one embodiment. The electronic device structure has fin 103 over insulating layer 104 on substrate 101. Substrate 101 is aligned along a first crystal plane corresponding to a first crystal orientation (e.g. (100) crystal plane), as described above. Fin 103 has surface 113 and surface 115 aligned along a second crystal plane corresponding to a second crystal orientation (e.g. (111) crystal plane), as described above.

FIG. 9 is a view 900 similar to FIG. 8 after insulating layer 104 is recessed according to one embodiment. Insulating layer 104 is recessed from the top surface down to a depth 123. In one embodiment, insulating layer 104 is recessed while leaving the fin 103 intact using a selective etching technique as described above. As shown in FIG. 9, insulating layer 102 is recessed down to a depth 123 that defines the height (“Hsi”) of the fin 103 relative to the top surface of the insulation layer 104. The height Hsi and the width (“Wsi”) of the fin 103 are typically determined by a design, as described above. In an embodiment, the height 123 relative to the top surface of the insulation layer 104 is from about 10 nm to about 200 nm, and more specifically, about 50 nm.

As shown in FIG. 9, a top portion 136 of the fin 103 has an M shape (“Structure C”). In an embodiment, portion 136 has sidewalls 114 and 115 aligned along a third crystal plane corresponding to a third crystal orientation (e.g., (110) crystal plane), and surfaces 112 and 113 aligned along a second crystal plane (e.g., (111 crystal plane) are adjacent to each other at a base 135.

In an embodiment, a TMAH wet etch solution at a temperature from about 30° C. to about 100° C. for time from about 30 seconds to about 150 seconds is used to anisotropically etch the Si fin to expose a surface of the fin corresponding to a (111) crystal plane to create Structure C. In an embodiment, at least one of KOH solution and NH4OH solution at a temperature from about 20° C. to about 80° C. and for time from about 30 seconds to about 150 seconds is used to anisotropically etch the Si fin to expose a surface of the fin corresponding to a (111) crystal plane to create Structure C.

FIG. 11 is a perspective view 1100 of an electronic device structure having a fin as depicted in FIG. 9 according to one embodiment. The electronic device structure has fin 103 over insulating layer 104 on substrate 101. Substrate 101 is aligned along a first crystal plane corresponding to a first crystal orientation (e.g., (100) crystal plane), as described above. Fin 103 has surface 113 and surface 115 aligned along a second crystal plane corresponding to a second crystal orientation (e.g., (111) crystal plane) and sidewalls 114 and 115 aligned along a third crystal plane corresponding to a third crystal orientation (e.g., (110) crystal plane), as described above.

FIGS. 18A-1, 18A-2, and 18A-3 show cross sectional scanning electron microscope (“XSEM”) pictures of the structures described above according to an embodiment.

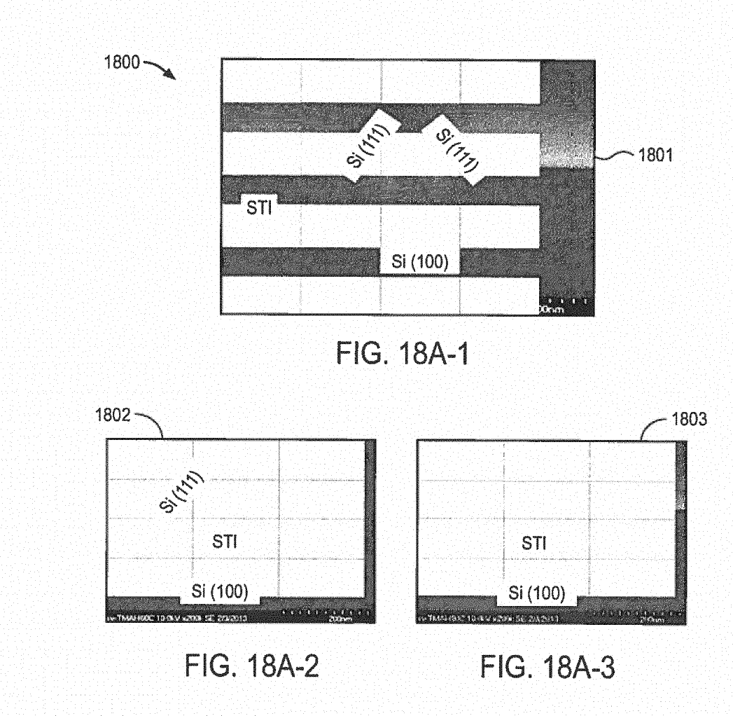

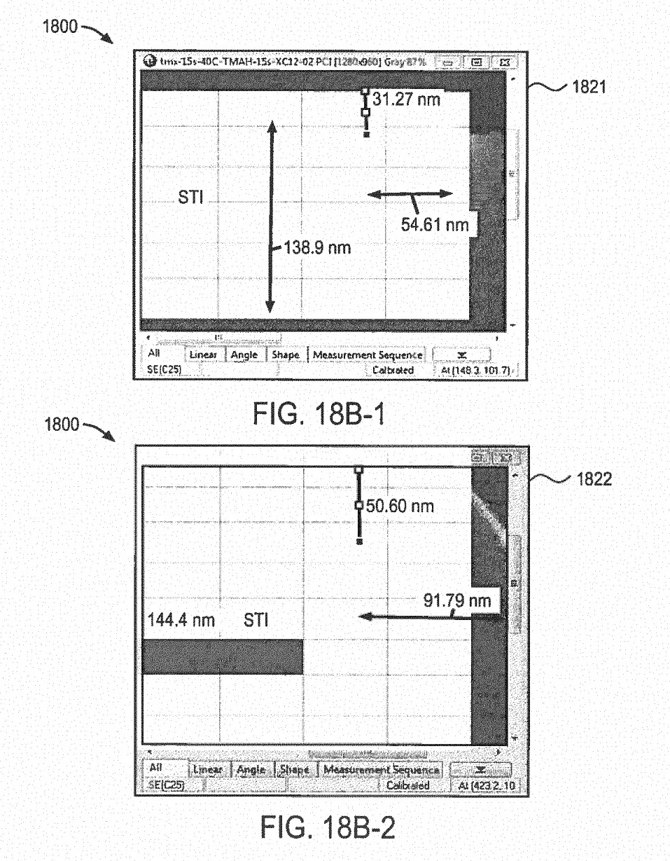

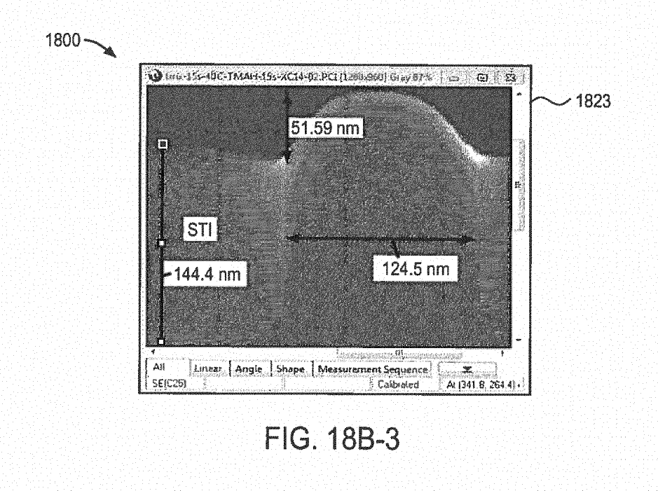

FIG. 18A-1 shows a picture 1801 illustrating a Si fin modified by an ex-situ etching according to one embodiment. The modified Si fin formed over insulating layer (STI) on Si substrate (100) has exposed Si surfaces (111). The modified Si fin has a triangular shape similar to Structure A, as described above.

FIG. 18A-2 shows a picture 1802 illustrating Si fins modified by an ex-situ etching according to one embodiment. The modified Si fins surrounded by the insulating layer (STI) on Si substrate (100) have exposed surfaces Si (111). Each of the modified Si fins has a V-shape similar to Structure B, as described above.

FIG. 18A-3 shows a picture 1802 illustrating Si fins modified by an ex-situ etching according to one embodiment. The modified Si fins on Si substrate (100) have exposed surfaces Si (111). The modified fins are separated by the insulating layer (STI) on the substrate. In an embodiment, the modified Si fin is formed based on a shape similar to Structure C, as described above.

FIGS. 18B-1, 18B-2, and 18B-3 show pictures 1821, 1822 and 1823 depicting the fins having different dimensions, after the fins have been etched in a TMAH solution for the same time according to one embodiment. As shown in pictures 1821, 1822 and 1823, depending on the initial fin width and height, the final profile of the fin changes.

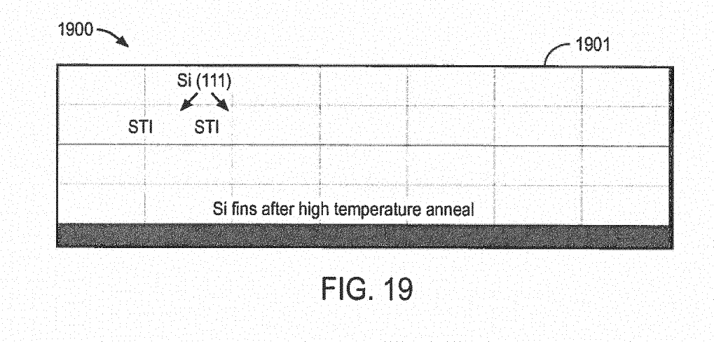

FIG. 19 is a view 1900 of a picture 1901 showing the reshaping of the fins with the high temperature anneal according to one embodiment.

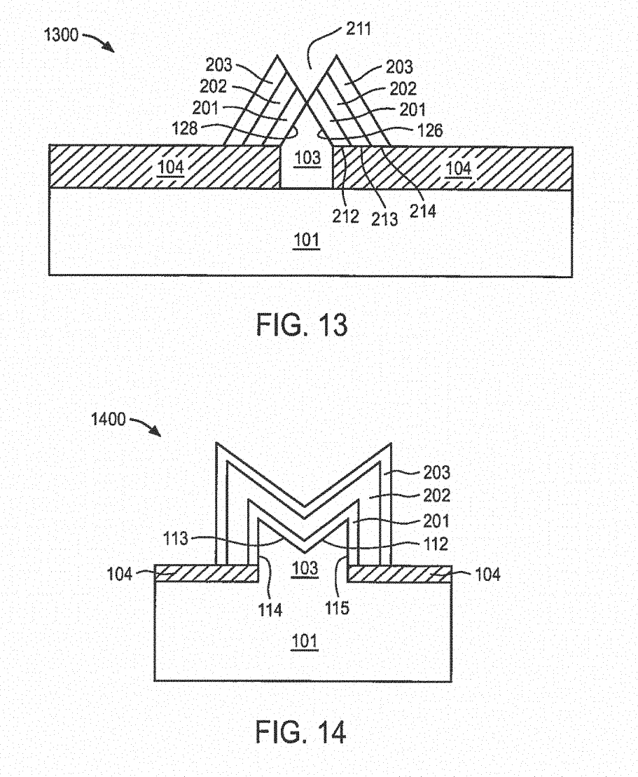

FIG. 13 is a cross-sectional view 1300 similar to FIG. 6, after an optional nucleation/seed layer is deposited on the surface of the fin aligned along the second crystal orientation, a device layer is deposited on the nucleation/seed layer, and a polarization inducing layer is deposited on the device layer according to one embodiment. An optional nucleation/seed layer 201 is deposited on surfaces 126 and 128 and on a portion 212 of insulating layer 104. A device layer 202 is deposited on optional nucleation/seed layer 201 and on a portion 213 of insulating layer 104. A polarization inducing layer 203 is deposited on device layer 202 and on a portion 214 of insulating layer 104. In an embodiment, polarization inducing layer 203 is deposited to induce a two-dimensional electron gas (“2DEG”) in device layer 202.

As shown in FIG. 13, optional nucleation/seed layer 201, device layer 202, and polarization inducing layer 203 extend away in directions perpendicular to the surfaces 126 and 128 of the fin 103. In some embodiments, optional nucleation/seed layer 201, device layer 202, and polarization inducing layer 203 can be laterally grown above a vertex portion 211 of the fin 103.

In an embodiment, a mismatch between the lattice parameter of the exposed surfaces 126 and 128 and the lattice parameter of the optional nucleation/seed layer 201 is reduced. Optional nucleation/seed layer 201 can be selectively deposited onto the surfaces 126 and 128 of the fin 103 using one of epitaxial techniques known to one of ordinary skill in the art of electronic device manufacturing, e.g., chemical vapor deposition (“CVD”), metalorganic chemical vapor deposition (“MOCVD”), atomic layer deposition (“ALD”), or other epitaxial growth technique known to one of ordinary skill in the art of electronic device manufacturing. In an embodiment, the optional nucleation/seed layer of aluminum nitride (“AlN”) is deposited onto the (111) surfaces of the silicon fin to the thickness from about 2 nm to about 25 nm.

In other embodiment, device layer 202 is deposited directly onto surfaces 126 and 128 of the fin. In an embodiment, a mismatch between the lattice parameter of the exposed surfaces 126 and 128 and the lattice parameter of the device layer 202 is substantially reduced.

In an embodiment, the device layer 202 includes a III-V material. In one embodiment, the device layer 202 includes a III-N material. In an embodiment, the device layer 202 is GaN, InGaN, any other III-N material, any other III-V material, or any combination thereof. The thickness of the device layer 202 determined by a device design. In an embodiment, the thickness of the device layer 202 is from about 1 nm to about 100 nm. In an embodiment, the device layer 202 includes a two-dimensional electron gas (“2DEG”) portion.

In an embodiment, device layer 202 is deposited over surfaces 128 and 126 using a selective area epitaxy. As shown in FIG. 13, device layer 202 is locally grown on the optional nucleation/seed layer. Epitaxial device layer 202 can be selectively deposited using one of epitaxial techniques known to one of ordinary skill in the art of electronic device manufacturing, e.g., chemical vapor deposition (“CVD”), metallo organic chemical vapor deposition (“MOCVD”), atomic layer deposition (“ALD”), or other epitaxial growth technique known to one of ordinary skill in the art of electronic device manufacturing.

In an embodiment, the polarization inducing layer 203 includes a III-V material. In one embodiment, the polarization inducing layer 203 includes a III-N material. In an embodiment, the polarization inducing layer 203 is AlGaN, InAlN, any other III-N material, any other III-V material, or any combination thereof. In an embodiment, the polarization inducing layer 203 is AlₓGa₁₋ₓN, where x is from about 0.2 to about 0.35. In an embodiment, the polarization inducing layer 203 is InₓAl₁₋ₓN, where x is from about 0.17 to about 0.22.

The thickness of the polarization inducing layer 203 is determined by a device design. In an embodiment, the thickness of the polarization inducing layer 203 is from about 3 nm to about 20 nm. In an embodiment, the polarization inducing layer 203 is deposited to induce the 2DEG into the device layer 203.

In an embodiment, polarization inducing layer 203 is deposited on device layer 202 using a selective area epitaxy. As shown in FIG. 13, polarization inducing layer 203 is locally grown on the optional device layer. Polarization inducing layer 203 can be selectively deposited using one of epitaxial techniques known to one of ordinary skill in the art of electronic device manufacturing, e.g., chemical vapor deposition (“CVD”), metal organic chemical vapor deposition (“MOCVD”), atomic layer deposition (“ALD”), or other epitaxial growth technique known to one of ordinary skill in the art of electronic device manufacturing.

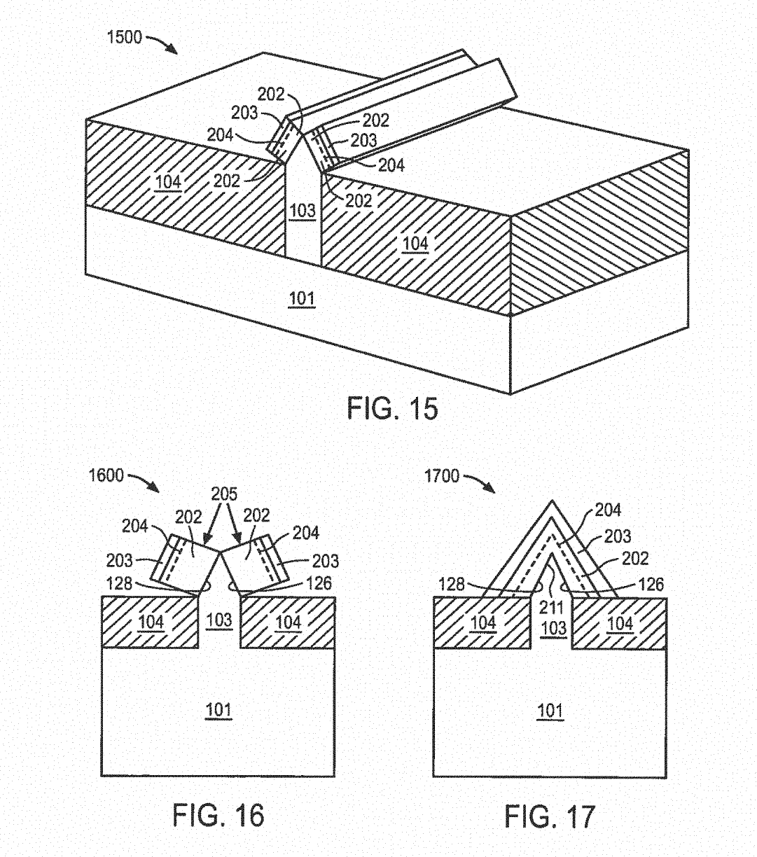

FIG. 16 is a cross-sectional view 1600 similar to FIG. 6, after a device layer is deposited on the surface of the fin aligned along the second crystal orientation, and a polarization inducing layer is deposited on the device layer according to another embodiment. FIG. 15 is a perspective view 1500 of an electronic device structure as depicted in FIG. 16. Device layer 202 is deposited on surfaces 126 and 128, as described above. A polarization inducing layer 203 is deposited on device layer 202, as described above. The electronic device structure shown in FIGS. 15 and 16 is different from the electronic device structure shown in FIG. 13 in that the device layer 202 is deposited directly onto surfaces 126 and 128 of the fin, and none of the device layer 202 and polarization inducing layer 203 extends up to the insulating layer 104. As shown in FIGS. 15 and 16, device layer 202, and polarization inducing layer 203 are spaced apart from insulating layer 104. As shown in FIGS. 15 and 16, the device layer 202 includes a two-dimensional electron gas (“2DEG”) portion 204 provided by polarization inducing layer 203, as described above. In an embodiment, a plane 205 along the thickness of the III-N material based device layer 202 is an m-plane (1-100). The m-plane in III-N materials is a non-polar plane, which means that crystals deposited on that plane do not possess any in-built polarization fields within them. Multi-quantum well structures of GaN/InGaN grown on the m-plane can be used to make light emitting devices that provide high illumination efficiency and do not suffer from light emission reduction due to polarization fields, which occurs for light emitting devices grown on the c-plane (denoted by surface normal to layer 203, 202). In an embodiment, a plane of the III-N material based polarization inducing layer 203 extending along the surfaces 126 and 128 of the fin 103 is a C-plane (0001) along which a two-dimensional electron gas 204 is induced.

FIG. 17 is a cross-sectional view 1700 similar to FIG. 6, after an optional nucleation/seed layer is deposited on the surface of the fin aligned along the second crystal orientation, a device layer is deposited on the nucleation/seed layer, and a polarization inducing layer is deposited on the device layer according to another embodiment. An optional nucleation/seed layer 201 is deposited on surfaces 126 and 128, as described above. A device layer 202 is deposited on optional nucleation/seed layer 201, as described above. A polarization inducing layer 203 is deposited on device layer 202, as described above. The electronic device structure shown in FIG. 15 is different from the electronic device structure shown in FIG. 13 in that the optional nucleation/seed layer 201, device layer 202, and polarization inducing layer 203 cover vertex portion 211 of the fin 103. As shown in FIG. 17, the device layer 202 includes a two-dimensional electron gas (“2DEG”) portion 204 provided by polarization inducing layer 203, as described above.

FIG. 14 is a cross-sectional view 1400 similar to FIG. 9, after an optional nucleation/seed layer is deposited on the surface of the fin aligned along the second crystal orientation, a device layer is deposited on the nucleation/seed layer, and a polarization inducing layer is deposited on the device layer according to one embodiment.

Optional nucleation/seed layer 201 is deposited on surfaces 126 and 128 and on sidewalls 114 and 115 of the fin 103 having an M-shape (structure C), as depicted in FIG. 9. As shown in FIG. 14, optional nucleation/seed layer 201, device layer 202, and polarization inducing layer 203 cover all four surfaces the fin 103, including surfaces 126 and 128 and sidewalls 114 and 115. In an embodiment, the optional nucleation/seed layer of aluminum nitride (“AlN”) is deposited onto the (111) surfaces and (110) sidewalls of the silicon fin to the thickness from about 2 nm to about 25 nm.

In an embodiment, a mismatch between the lattice parameter of the exposed surfaces 126 and 128 and the lattice parameter of the optional nucleation/seed layer 201 is reduced. That is, depositing optional nucleation/seed layer layer 201 on surfaces 126, 128, and sidewalls 114 and 115 leads to lower lattice mismatch than what would have been if optional nucleation/seed layer 201 was deposited on surface 107.

Optional nucleation/seed layer 201 can be selectively deposited onto the surfaces 126 and 128, and sidewalls 114 and 115 of the fin 103 using one of epitaxial techniques known to one of ordinary skill in the art of electronic device manufacturing, e.g., chemical vapor deposition (“CVD”), metallo organic chemical vapor deposition (“MOCVD”), atomic layer deposition (“ALD”), molecular beam epitaxy (MBE) or other epitaxial growth technique known to one of ordinary skill in the art of electronic device manufacturing, as described above.

Device layer 202 is deposited on optional nucleation/seed layer 201, as described above. In an embodiment, device layer 202 is deposited directly onto surfaces 126 and 128 and (110) sidewalls 114 and 115 of the fin. In an embodiment, a mismatch between the lattice parameter of the exposed surfaces 126 and 128 and the lattice parameter of the device layer 202 is substantially reduced, as described above. That is, depositing device layer 202 on surfaces 126, 128, and sidewalls 114 and 115 leads to lower lattice mismatch than what would have been if device layer 202 was deposited on surface 107. For example, the lattice mismatch between GaN and Si (100) is about 40%, between GaN and Si (111) is about 17% and GaN and Si (110) is about 20. Depositing at least one of GaN device layer and GaN nucleation/seed layer on at least one of surfaces of Si (111) and Si (110) instead of depositing at least one of GaN device layer and GaN nucleation/seed layer on Si (100) will reduce the lattice mismatch between the at least one of GaN device layer and GaN nucleation/seed layer and Si substrate by at least a factor of two. Polarization inducing layer 203 is deposited on device layer 202, as described above.

Because the mismatch between the lattice parameter of the exposed (111) surfaces of the Si fin and the lattice parameter of the III-N device layer is substantially reduced, embodiments described herein provide an advantage of not requiring the use of thick buffer layers. Embodiments described herein reduce the growth time, cost and provide easier integration of III-N devices into a Si SoC process flow comparing with conventional techniques. The GaN or III-N material is grown on Si (111) planes instead of Si (100) plane. The Si (111) planes are created on a nanoscale template and can have different shapes and geometry defined by a device design, as described above. This is a novel way of getting the best of both worlds for III-N epitaxy: using a starting Si (111) template on a Si (100) large area wafer which can have CMOS circuits on it and lead to co-integration of III-N transistors and Si CMOS. Because the Si templates are nanoscale, the Si substrate is more compliant for device integration. Because of the three dimensional nature of the nano-features (e.g., fins) a lot of free surface area is available to the epilayer for free surface relaxation. Embodiments described herein allow deposition of III-N films on Si (111) templates on Si(100) substrate with substantially reduced defect density and can result in substantially defect free III-N material.

Modifying an initial template (fin) for III-N material growth on Si (100) to provide nanotemplates (e.g., fins, or any other nanostructures) with (111) planes makes the starting substrate more compliant for III-N material epitaxy, and hence able to absorb some of the lattice mismatch strain. The shape of the nanotemplate also directly affects the free surface area available to the epi-layer for free surface relaxation. These factors can reduce the challenge of integration of large lattice mismatched systems on Si, reduce the thickness of the III-N material based epi layer grown on the Si substrate, and reduce defect density in the III-N material based epi film. Si (111) has a lower lattice mismatch to GaN as compared to Si (100). Si (111) also has a unit cell which is hexagonal in symmetry and hence aids in better crystal registry of the hexagonal GaN unit cell on top of it. This may not be the case for Si (100), where the unit cell has a cubic (diamond lattice structure) symmetry and thus orienting a hexagonal crystal (III-N material) on the cubic material may result in formation of multi-domains.

The growth of III-N materials (GaN, AlGaN, InGaN, InAlN) on the nanotemplates with Si (111) planes as described herein has following advantages:

1 GaN crystal structure has hexagonal symmetry and so does the Si (111) unit cell. As such it is easier to epitaxially nucleate crystalline GaN on Si (111). Si (111) also offers a double step structure on the surface and thus growth of polar materials (like GaN) on this surface does not generate defects like antiphase domains.

2 GaN has lower lattice mismatch to Si (111) [17%] as opposed to Si (100) [˜40%] using conventional methods.

3 A nanotemplate, e.g., a fin or a nanoribbon or nanowire as described herein offers several advantages for growth of lattice mismatched epi films. The substrate is now compliant, due to less substrate volume and also due to the shape of the nanotemplate having free surfaces available for the epi film to undergo free surface relaxation. The structures described herein have even more reduced substrate volume as compared to a conventional fin (which has a greater H_{Si}), and the more reduced substrate volume will result in more substrate compliance for epi-film growth.

4 The growth of GaN on the nanotemplates as described herein does not require the use of “buffer” layers which are usually thick layers (e.g., greater than 1.5 microns). The buffer layers in blanket film deposition try to keep the dislocation defects at the bottom interface between the epi-layer and substrate. Using methods described herein, which are “bufferless”, one can grow thin layers (e.g., from about 1 nm to about 40 nm) of epi films and due to the strain sharing effects because of substrate compliance and free surface relaxation, result in thin films of III-N materials on Si with low defect density suitable for device layers.

5 Growth of GaN on the structures as described herein can also result in the growth of GaN crystals with multiple crystal planes of GaN simultaneously. This is explained with respect to FIG. 16. Conventional epitaxy results in the growth of one preferred crystal plane only. For example, growth of GaN on Si (111) or Si (100) blanket wafers can lead to the growth of GaN c-plane (0001) only. Due to the unique structure of these nanotemplates, we can form structures where multiple crystal planes of GaN (e.g., a C-plane (0001) and an m-plane (1-100) as described in FIG. 16) can be formed by varying growth conditions and these can be useful in certain device and LED operations. Also this is quite unique to GaN like materials, wurtzite class of crystals, as the crystal planes in this lattice system are not symmetric and hence also have dissimilar material and electrical properties.

6 In addition to growing GaN transistors for SoC application, embodiments described herein can also be applied to the growth of GaN based epi layers for LEDs and laser diodes. The fact that multiple crystal planes can coexist, can result in LED structures with different wavelength spectra and high efficiencies.

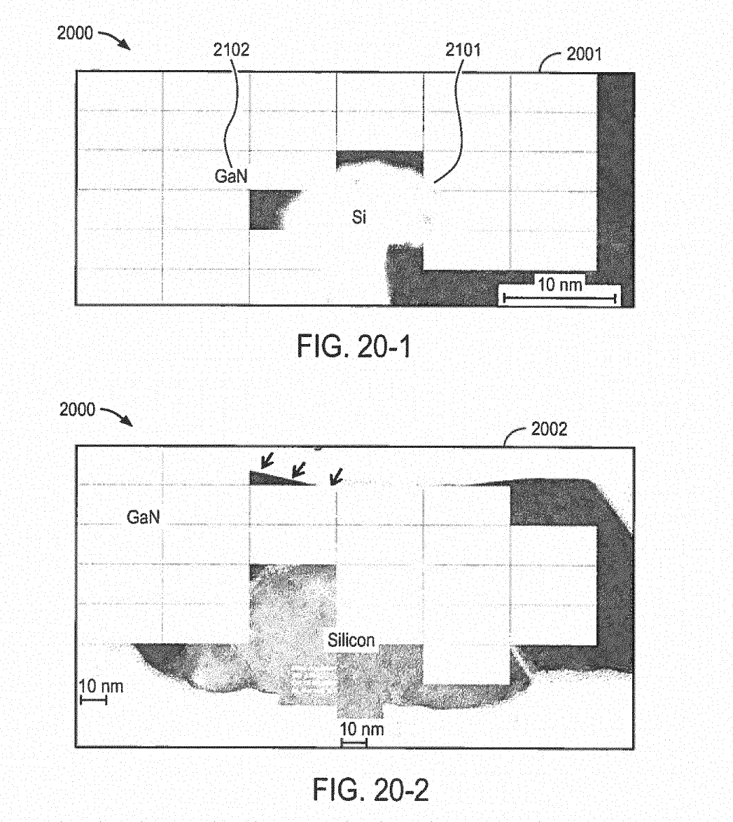

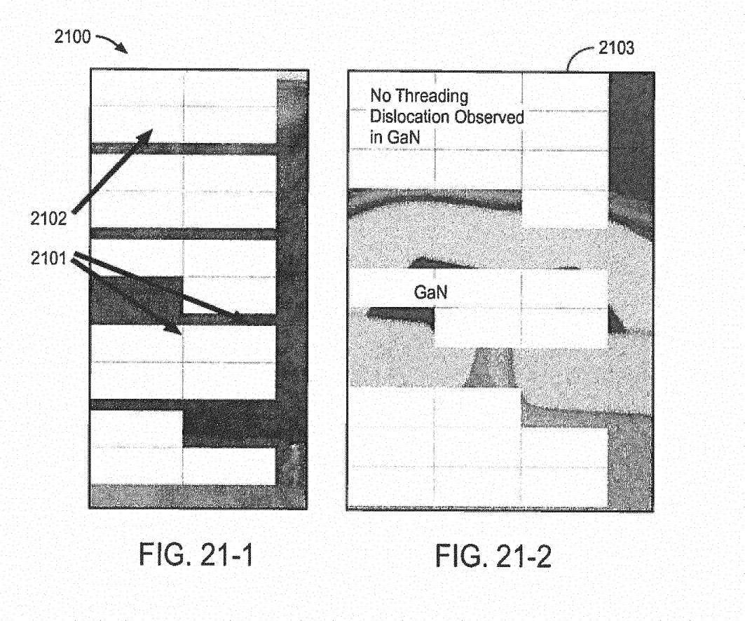

FIGS. 20-1, 20-2, 21-1, and 21-2 illustrate growth of the III-N material layers on Si (111) like planes according to an embodiment. A picture 2001 shows an energy-dispesive x-ray spectroscopy (“EDX”) mapping including a layer GaN 2102 on a layer of MN 2101 on a silicon fin having exposed (111) planes. A picture 2001 is a HRTEM image showing the presence of almost no threading dislocation defects in the GaN layer (device layer for future SoC applications). Defects may be formed in the silicon fin that may be the result of effective strain transfer to the silicon fin, and due to the lower volume of the Si fin than that of the GaN layer, the Si fin starts to form the defects to accommodate the misfit strain. A picture 2100 shows a state of the art GaN device with a buffer layer of thickness ˜2 microns. As shown in picture 2100, the state of the art GaN stack on Si (100) has threading dislocation defects 2102 and 2101. A picture 2103 shows a GaN layer deposited on a Si nanostructured fin as described herein. There are no threading dislocations observed in GaN, as shown in picture 2103.

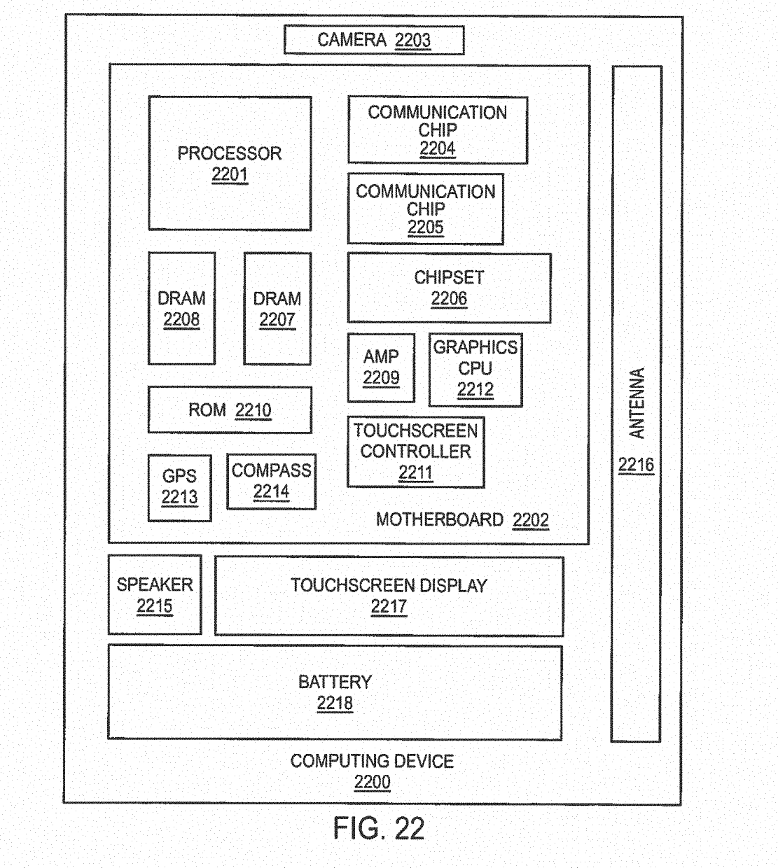

FIG. 22 illustrates a computing device 2200 in accordance with one embodiment. The computing device 2200 houses a board 2202. The board 2202 may include a number of components, including but not limited to a processor 2201 and at least one communication chip 2204. The processor 2201 is physically and electrically coupled to the board 2202. In some implementations at least one communication chip is also physically and electrically coupled to the board 2202. In further implementations, at least one communication chip 2204 is part of the processor 2201.

Depending on its application, computing device 2200 may include other components that may or may not be physically and electrically coupled to the board 2202. These other components include, but are not limited to, a memory, such as a volatile memory 2208 (e.g., a DRAM), a non-volatile memory 2210 (e.g., ROM), a flash memory, a graphics processor 2212, a digital signal processor (not shown), a crypto processor (not shown), a chipset 2206, an antenna 2216, a display, e.g., a touchscreen display 2217, a display controller, e.g., a touchscreen controller 2211, a battery 2218, an audio codec (not shown), a video codec (not shown), an amplifier, e.g., a power amplifier 2209, a global positioning system (GPS) device 2213, a compass 2214, an accelerometer (not shown), a gyroscope (not shown), a speaker 2215, a camera 2203, and a mass storage device (such as hard disk drive, compact disk (CD), digital versatile disk (DVD), and so forth) (not shown).

A communication chip, e.g., communication chip 2204, enables wireless communications for the transfer of data to and from the computing device 2200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2204 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 2200 may include a plurality of communication chips. For instance, a communication chip 2204 may be dedicated to shorter range wireless communications such as Wi-Fi and Bluetooth and a communication chip 2236 may be dedicated to longer range wireless communications such as GPS, EDGE, GPRS, CDMA, WiMAX, LTE, Ev-DO, and others.

In at least some embodiments, the processor 2201 of the computing device 2200 includes an integrated circuit die packaged with an integrated heat spreader design that maximizes heat transfer from a multi-chip package as described herein. The integrated circuit die of the processor includes one or more devices, such as transistors or metal interconnects as described herein. The term “processor” may refer to any device or portion of a device that processes electronic data from registers and/or memory to transform that electronic data into other electronic data that may be stored in registers and/or memory. The communication chip 2205 also includes an integrated circuit die package an integrated heat spreader design that maximizes heat transfer from a multi-chip package according to the embodiments described herein. In further implementations, another component housed within the computing device 2200 may contain an integrated circuit die package having an integrated heat spreader design that maximizes heat transfer from a multi-chip package according to embodiments described herein. In accordance with one implementation, the integrated circuit die of the communication chip includes one or more devices, such as transistors and metal interconnects, as described herein. In various implementations, the computing device 2200 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 2200 may be any other electronic device that processes data.

The following examples pertain to further embodiments:

A method to manufacture an electronic device comprising modifying a fin over an insulating layer on a substrate aligned along a first crystal orientation to form a surface aligned along a second crystal orientation; and depositing a device layer over the surface of the fin aligned along the second crystal orientation.

A method to manufacture an electronic device comprising modifying a fin over an insulating layer on a substrate aligned along a first crystal orientation to form a surface aligned along a second crystal orientation; depositing a nucleation layer on the surface of the fin aligned along the second crystal orientation; and depositing a device layer on the nucleation layer.

A method to manufacture an electronic device comprising modifying a fin over an insulating layer on a substrate aligned along a first crystal orientation to form a surface aligned along a second crystal orientation; and depositing a device layer over the surface of the fin aligned along the second crystal orientation, wherein modifying the fin comprises etching the fin to expose the surface aligned along the second crystal orientation.

A method to manufacture an electronic device comprising modifying a fin over an insulating layer on a substrate aligned along a first crystal orientation to form a surface aligned along a second crystal orientation; and depositing a device layer over the surface of the fin aligned along the second crystal orientation, wherein modifying the fin comprises annealing the fin to form the surface aligned along the second crystal orientation.

A method to manufacture an electronic device comprising modifying a fin over an insulating layer on a substrate aligned along a first crystal orientation to form a surface aligned along a second crystal orientation; and depositing a device layer over the surface of the fin aligned along the second crystal orientation, wherein the substrate includes silicon, and the device layer includes a III-V material.

A method to manufacture an electronic device comprising modifying a fin over an insulating layer on a substrate aligned along a first crystal orientation to form a surface aligned along a second crystal orientation; depositing a device layer over the surface of the fin aligned along the second crystal orientation; and depositing a polarization inducing layer on the device layer to provide a two-dimensional electron gas.

A method to manufacture an electronic device comprising etching the substrate through a mask to form a fin; depositing the insulating layer on the substrate; modifying the fin over the insulating layer on the substrate aligned along a first crystal orientation to form a surface aligned along a second crystal orientation; depositing a device layer over the surface of the fin aligned along the second crystal orientation.

A method to manufacture an electronic device comprising modifying a fin over an insulating layer on a substrate aligned along a first crystal orientation to form a surface aligned along a second crystal orientation; and depositing a device layer over the surface of the fin aligned along the second crystal orientation, wherein the first crystal orientation is a <100> crystal orientation, and the second crystal orientation is a <111> crystal orientation.

A method to manufacture an electronic device comprising modifying a fin over an insulating layer on a substrate aligned along a first crystal orientation to form a surface aligned along a second crystal orientation; and depositing a device layer over the surface of the fin aligned along the second crystal orientation, wherein the thickness of the device layer is from 1 nanometer to 40 nanometers.

A method to manufacture an electronic device comprising modifying a fin over an insulating layer on a substrate aligned along a first crystal orientation to form a surface aligned along a second crystal orientation; and depositing a device layer over the surface of the fin aligned along the second crystal orientation, wherein the width of the first fin is less than the height of the first fin.

An electronic device comprising a fin over an insulating layer on a substrate aligned along a first crystal orientation, the fin having a first surface aligned along a second crystal orientation; and a device layer deposited over the first surface of the fin aligned along the second crystal orientation.

An electronic device comprising a fin over an insulating layer on a substrate aligned along a first crystal orientation, the fin having a first surface aligned along a second crystal orientation; and a nucleation layer on the first surface of the fin aligned along the second crystal orientation and the device layer on the nucleation layer.

An electronic device comprising a fin over an insulating layer on a substrate aligned along a first crystal orientation, the fin having a first surface aligned along a second crystal orientation; a device layer deposited over the first surface of the fin aligned along the second crystal orientation, and a polarization inducing layer on the device layer to provide a two-dimensional electron gas.

An electronic device comprising a fin over an insulating layer on a substrate aligned along a first crystal orientation, the fin having a first surface aligned along a second crystal orientation; and a device layer deposited over the first surface of the fin aligned along the second crystal orientation, wherein the fin has a second surface aligned along the second crystal orientation adjacent to the first surface.

An electronic device comprising a fin over an insulating layer on a substrate aligned along a first crystal orientation, the fin having a first surface aligned along a second crystal orientation; and a device layer deposited over the first surface of the fin aligned along the second crystal orientation, wherein the fin has a triangular shape.

An electronic device comprising a fin over an insulating layer on a substrate aligned along a first crystal orientation, the fin having a first surface aligned along a second crystal orientation; and a device layer deposited over the first surface of the fin aligned along the second crystal orientation, wherein the fin has a V shape.

An electronic device comprising a fin over an insulating layer on a substrate aligned along a first crystal orientation, the fin having a first surface aligned along a second crystal orientation; and a device layer deposited over the first surface of the fin aligned along the second crystal orientation, wherein the fin has an M shape.

An electronic device comprising a fin over an insulating layer on a substrate aligned along a first crystal orientation, the fin having a first surface aligned along a second crystal orientation; and a device layer deposited over the first surface of the fin aligned along the second crystal orientation, wherein the substrate includes silicon; and the device layer includes a III-V material.

An electronic device comprising a fin over an insulating layer on a substrate aligned along a first crystal orientation, the fin having a first surface aligned along a second crystal orientation; and a device layer deposited over the first surface of the fin aligned along the second crystal orientation, wherein the first crystal orientation is a <100> crystal orientation, and the second crystal orientation is a <111> crystal orientation.

An electronic device comprising a fin over an insulating layer on a substrate aligned along a first crystal orientation, the fin having a first surface aligned along a second crystal orientation; and a device layer deposited over the first surface of the fin aligned along the second crystal orientation, wherein the thickness of the device layer is from 1 nanometer to 40 nanometers.

What is claimed is:

1. An electronic device, comprising
a fin over an insulating layer on a substrate aligned along a first crystal orientation, the fin having first surfaces that cross each other, wherein each of the first surfaces corresponds to a second crystal orientation; and
a device layer deposited on the first surfaces.

2. The electronic device of claim 1, further comprising
a nucleation layer between the first surfaces of the fin and the device layer.

3. The electronic device of claim 1, further comprising a polarization inducing layer on the device layer to provide a two-dimensional electron gas.

4. The electronic device of claim 1, wherein the width of the fin is less than the height of the fin.

5. The electronic device of claim 1, wherein the fin has a triangular shape, a V shape, or an M shape.

6. The electronic device of claim 1, wherein the fin includes silicon; and the device layer includes a III-V material.

7. The electronic device of claim 1, wherein the first crystal orientation is a <100> crystal orientation, and the second crystal orientation is a <111> crystal orientation.

8. The electronic device of claim 1, wherein the thickness of the device layer is from 1 nanometer to 40 nanometers.

9. The electronic device of claim 1, wherein the fin includes silicon; and the device layer includes a III-N material.

10. A computing system comprising:
a chip including
an electronic device comprising
a fin over an insulating layer on a substrate aligned along a first crystal orientation, the fin having first surfaces that cross each other, wherein each of the first surfaces corresponds to a second crystal orientation; and
a device layer deposited on the first surfaces.

11. The computing system of claim 10, wherein the electronic device further comprises a nucleation layer between the fin and the device layer.

12. The computing system of claim 10, wherein the electronic device further comprises a polarization inducing layer on the device layer to provide a two-dimensional electron gas.

13. The computing system of claim 10, wherein the width of the fin is less than the height of the fin.

14. The computing system of claim 10, wherein the fin has a triangular shape, a V shape, or an M shape.

15. The computing system of claim 10, wherein the fin includes silicon; and the device layer includes a III-V material.

16. The computing system of claim 10, wherein the first crystal orientation is a <100> crystal orientation, and the second crystal orientation is a <111> crystal orientation.

17. The computing system of claim 10, wherein the thickness of the device layer is from 1 nanometer to 40 nanometers.

18. The computing system of claim 10, wherein the fin includes silicon; and the device layer includes a III-N material.
